(19) United States
(12) Patent Application Publication
(10) Pub. No.: US 2025/0231831 A1
(43) Pub. Date: Jul. 17, 2025

(54) DETERIORATION CORRECTION CIRCUITRY

(71) Applicant: Micron Technology, Inc., Boise, ID (US)

(72) Inventors: Leon Zlotnik, Camino, CA (US); Leonid Minz, Beer Sheva (IL)

(21) Appl. No.: 19/013,680

(22) Filed: Jan. 8, 2025

Related U.S. Application Data
(60) Provisional application No. 63/620,023, filed on Jan. 11, 2024.

(51) Int. Cl. G06F 11/07; G01R 31/28

(52) U.S. Cl. CPC G06F 11/0793; G01R 31/2837; G06F 11/0721

(57) ABSTRACT

Deterioration correction circuitry can continually provide power and a first signal to a first circuitry to generate a first output. Power and a second signal can be provided periodically to a second circuitry to generate a second output. The first circuitry and the second circuitry are different instances of a same circuitry. A deterioration of the first circuitry can be measured by comparing the first output of the first circuitry with the second output of the second circuitry. Responsive to measuring the deterioration of the first circuitry, the deterioration of the first circuitry can be compared with a threshold. Responsive to determining that the deterioration is greater than the threshold, a corrective action can be performed to limit effects of a deterioration of a system based on the deterioration of the first circuitry.

### PRIORITY INFORMATION

This application claims the benefit of U.S. Provisional Application No. 63/620,023, filed on Jan. 11, 2023, the contents of which are incorporated herein by reference.

### TECHNICAL FIELD

Embodiments of the disclosure relate generally to accessing memory, and more specifically, relate to deterioration correction circuitry.

### BACKGROUND

Various types of electronic devices such as digital logic circuits and memory systems may store and process data. A digital logic circuit is an electronic circuit that processes digital signals or binary information, which can take on two possible values (usually represented as 0and 1). The digital logic circuit can use logic gates to manipulate and transform the digital signals or binary information. Digital logic circuits can be, for example, used in a wide range of electronic devices including computers, calculators, digital clocks, and many other electronic devices that employ digital processing. Digital logic circuits can be designed to perform specific logical operations on digital inputs to generate digital outputs, and, in some instances, can be combined to form more complex circuits to perform more complex operations. A memory device can include one or more memory devices that store data. The memory devices can be, for example, non-volatile memory devices and volatile memory devices. In general, a host system can utilize a memory system to store data at the memory devices and to retrieve data from the memory devices. The memory device can deteriorate over time based on a number of factors.

### BRIEF DESCRIPTION OF THE DRAWINGS

The present disclosure will be understood more fully from the detailed description given below and from the accompanying drawings of various embodiments of the disclosure.

FIG. 1 illustrates an example computing system that includes a memory sub-system in accordance with some embodiments of the present disclosure.

FIG. 2 illustrates a block diagram of an aging monitor in accordance with some embodiments of the present disclosure.

FIG. 3 illustrates a block diagram of various aging monitors coupled to multiple measurement circuitry in accordance with some embodiments of the present disclosure.

FIG. 4 illustrates a block diagram of multiple aging monitors coupled to measurement circuitry in accordance with some embodiments of the present disclosure.

FIG. 5 illustrates a block diagram of multiple aging monitors that receive power from multiple voltage regulators in accordance with some embodiments of the present disclosure.

FIG. 6 is a flow diagram corresponding to a method for implementing deterioration correction circuitry in accordance with some embodiments of the present disclosure.

FIG. 7 is a block diagram of an example computer system in which embodiments of the present disclosure may operate.

### DETAILED DESCRIPTION

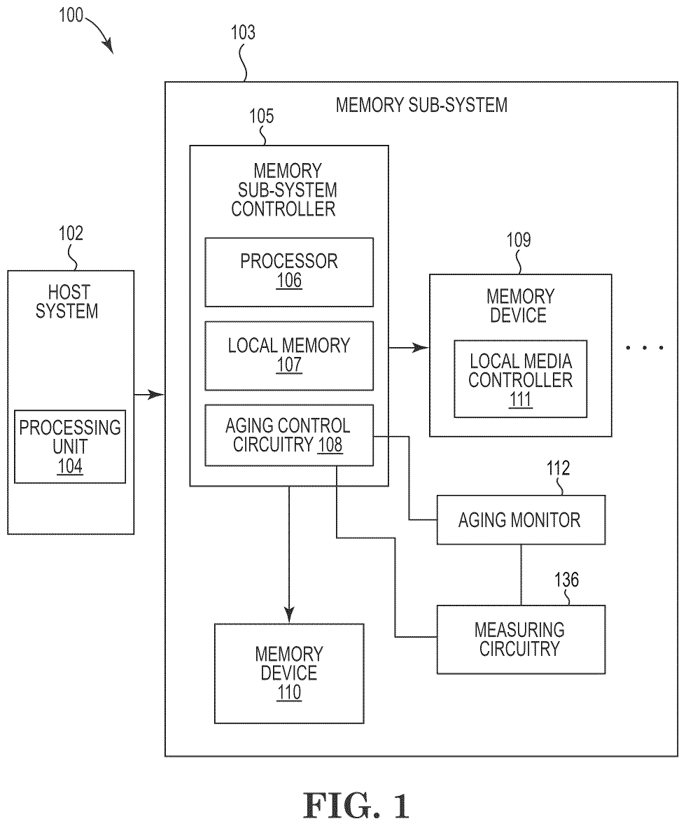

Aspects of the present disclosure are directed to deterioration correction circuitry. Power and a first signal can be continuously provided to a first circuitry to generate a first output. Power and a second signal can be periodically provided to a second circuitry to generate a second output. The first circuitry and the second circuitry can be different instances of a same circuitry. A deterioration of the first circuitry can be measured by comparing the first output of the first circuitry with the second output of the second circuitry. Responsive to measuring the deterioration of the first circuitry, the deterioration of the first circuitry can be compared with a threshold. Responsive to determining that the deterioration is greater than the threshold, a corrective action can be performed to limit effects of a deterioration on a system based on the deterioration of the first circuitry. The system can be a memory sub-system. The memory sub-system can be a storage system, storage device, a memory module, or a combination of such. An example of a memory sub-system is a storage system such as a solid-state drive (SSD). Examples of storage devices and memory modules are described below in conjunction with FIG. 1, et alibi. In general, a host system can utilize a memory sub-system that includes one or more components, such as memory devices that store data. The host system can provide data to be stored at the memory sub-system and can request data to be retrieved from the memory sub-system. The host system can also cause a deterioration of the memory sub-system to be measured.

Although some non-limiting examples herein are generally described in terms of applicability to memory sub-systems and/or to memory devices, embodiments are not so limited, and aspects of the present disclosure can be applied as well to systems such as computer systems. The embodiments describe can be applicable to a system-on-a-chip, computing sub-system, data collection and processing, storage, networking, communication, power, artificial intelligence, control, telemetry, sensing and monitoring, digital entertainment and other types of systems/sub-systems and/or devices.

In various instances, a delay of cells of the system can deteriorate (e.g., increase) during the lifespan of the system. For example, a deterioration of the system can accelerate due to the aging of the system in combination with a temperature of the system and/or a voltage of the system, among other factors that can contribute to the deterioration of the system. As the system ages, the cells of the system can experience deterioration which can contribute to user experience. For example, the system can experience a voltage drift as the system ages. As used herein, the deterioration of the system can also be referred to as the degradation of the system. The deterioration of the system can refer to a loss of functionality over time as compared to a specification of the system. For example, a voltage drift over time can be referred to as a deterioration of the system given that a specification of the system utilized a first voltage and/or the system utilized the first voltage when the system was manufactured but utilized a second voltage after the system has aged.

In order to address these and other deficiencies of current approaches, embodiments of the present disclosure implement an aging monitor. The aging monitor emulates a deterioration of the system and/or a deterioration of an application-specific integrated circuitry (ASIC) of the system. The aging monitor can include two or more identical gate chains. One of the gate chains can remain powered to emulate the power status of the system. The other gate chain may remain unpowered until a deterioration measurement is performed.

Periodically, the gate chains (e.g., the other gate chain) of the aging monitor can be powered to generate outputs (e.g., output signals). The output signals can be utilized to measure a deterioration of the system. The deterioration of the system can be due to, at least in part, an aging of the system. Based on the deterioration of the system and/or the aging of the system as measured using the output signals, the system may implement corrective actions to mitigate the deterioration of the system. In various instances, the deterioration of the system can be mitigated by decreasing the clock frequency of the system and/or increasing the supply voltage of the system. An aging of the system that approaches an irreparable stage can be indicated to the system and/or an end user of the system.

FIG. 1 illustrates an example computing system 100 that includes a memory sub- system 103 in accordance with some embodiments of the present disclosure. The memory sub- system 103 can include media, such as one or more volatile memory devices (e.g., memory device 110), one or more non-volatile memory devices (e.g., memory device 109), or a combination of such.

A memory sub-system 103 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, server, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

In other embodiments, the computing system 100 can be deployed on, or otherwise included in a computing device such as a desktop computer, laptop computer, server, network server, mobile computing device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device. As used herein, the term “mobile computing device” generally refers to a handheld computing device that has a slate or phablet form factor. In general, a slate form factor can include a display screen that is between approximately 3 inches and 5.2 inches (measured diagonally), while a phablet form factor can include a display screen that is between approximately 5.2 inches and 7 inches (measured diagonally). Examples of “mobile computing devices” are not so limited, however, and in some embodiments, a “mobile computing device” can refer to an IoT device, among other types of edge computing devices.

The computing system 100 can include a host system 102 that is coupled to one or more memory sub-systems 103. In some embodiments, the host system 102 is coupled to different types of memory sub-system 103. FIG. 1 illustrates one example of a host system 102 coupled to one memory sub-system 103. As used herein, “coupled to” or “coupled with” generally refers to a connection between components, which can be an indirect communicative connection or direct communicative connection (e.g., without intervening components), whether wired or wireless, including connections such as electrical, optical, magnetic, and the like.

The host system 102 can include a processor chipset and a software stack executed by the processor chipset. The processor chipset can include one or more cores, one or more caches, a memory controller (e.g., an SSD controller), and a storage protocol controller (e.g., PCIe controller, SATA controller). The host system 102 uses the memory sub-system 103, for example, to write data to the memory sub-system 103 and read data from the memory sub-system 103.

The host system 102 includes a processing unit 104. The processing unit 104 can be a central processing unit (CPU) that is configured to execute an operating system. In some embodiments, the processing unit 104 comprises a complex instruction set computer architecture, such an x86 or other architecture suitable for use as a CPU for a host system 102.

The host system 102 can be coupled to the memory sub-system 103 via a physical host interface. Examples of a physical host interface include, but are not limited to, a serial advanced technology attachment (SATA) interface, a peripheral component interconnect express (PCIe) interface, universal serial bus (USB) interface, Fibre Channel, Serial Attached SCSI (SAS), Small Computer System Interface (SCSI), a double data rate (DDR) memory bus, a dual in-line memory module (DIMM) interface (e.g., DIMM socket interface that supports Double Data Rate (DDR)), Open NAND Flash Interface (ONFI), Double Data Rate (DDR), Low Power Double Data Rate (LPDDR), or any other interface. The physical host interface can be used to transmit data between the host system 102 and the memory sub-system 103. The host system 102 can further utilize an NVM Express (NVMe) interface to access components (e.g., memory devices 109) when the memory sub-system 103 is coupled with the host system 102 by the PCIe interface. The physical host interface can provide an interface for passing control, address, data, and other signals between the memory sub-system 103 and the host system 102. FIG. 1 illustrates a memory sub-system 103 as an example. In general, the host system 102 can access multiple memory sub-systems via the same communication connection, multiple separate communication connections, and/or a combination of communication connections.

The memory devices 109, 110 can include any combination of the different types of non-volatile memory devices and/or volatile memory devices. The volatile memory devices (e.g., memory device 110) can be, but are not limited to, random access memory (RAM), such as dynamic random-access memory (DRAM) and synchronous dynamic random access memory (SDRAM).

Some examples of non-volatile memory devices (e.g., memory device 109) include negative-and (NAND) type flash memory and write-in-place memory, such as three-dimensional cross-point (“3D cross-point”) memory device, which is a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 109, 110 can include one or more arrays of memory cells. One type of memory cell, for example, single level cells (SLC) can store one bit per cell.

Other types of memory cells, such as multi-level cells (MLCs), triple level cells (TLCs), quad- level cells (QLCs), and penta-level cells (PLC) can store multiple bits per cell. In some embodiments, each of the memory devices 109 can include one or more arrays of memory cells such as SLCs, MLCs, TLCs, QLCs, or any combination of such. In some embodiments, a particular memory device can include an SLC portion, an MLC portion, a TLC portion, a QLC portion, or a PLC portion of memory cells. The memory cells of the memory devices 109 can be grouped as pages that can refer to a logical unit of the memory device used to store data. With some types of memory (e.g., NAND), pages can be grouped to form blocks.

Although non-volatile memory components such as three-dimensional cross-point arrays of non-volatile memory cells and NAND type memory (e.g., 2D NAND, 3D NAND) are described, the memory device 109 can be based on any other type of non-volatile memory or storage device, such as such as, read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, and electrically erasable programmable read-only memory (EEPROM).

The memory sub-system controller 105 (or controller 105 for simplicity) can communicate with the memory devices 109, 110 to perform operations such as reading data, writing data, or erasing data at the memory devices 109, 110 and other such operations. The memory sub-system controller 105 can include hardware such as one or more integrated circuits and/or discrete components, a buffer memory, or a combination thereof. The hardware can include digital circuitry with dedicated (i.e., hard-coded) logic to perform the operations described herein. The memory sub-system controller 105 can be a microcontroller, special purpose logic circuitry (e.g., a field programmable gate array (FPGA), an application specific integrated circuit (ASIC), etc.), or other suitable processor.

The memory sub-system controller 105 can include a processor 106 (e.g., a processing device) configured to execute instructions stored in a local memory 107. In the illustrated example, the local memory 107 of the memory sub-system controller 105 includes an embedded memory configured to store instructions for performing various processes, operations, logic flows, and routines that control operation of the memory sub-system 103, including handling communications between the memory sub-system 103 and the host system 102.

In some embodiments, the local memory 107 can include memory registers storing memory pointers, fetched data, etc. The local memory 107 can also include read-only memory (ROM) for storing micro-code. While the example memory sub-system 103 in FIG. 1 has been illustrated as including the memory sub-system controller 105, in another embodiment of the present disclosure, a memory sub-system 103 does not include a memory sub-system controller 105, and can instead rely upon external control (e.g., provided by an external host, or by a processor or controller separate from the memory sub-system).

In general, the memory sub-system controller 105 can receive commands or operations from the host system 102 and can convert the commands or operations into instructions or appropriate commands to achieve the desired access to the memory device 109 and/or the memory device 110. The memory sub-system controller 105 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address, physical media locations, etc.) that are associated with the memory devices 109. The memory sub-system controller 105 can further include host interface circuitry to communicate with the host system 102 via the physical host interface. The host interface circuitry can convert the commands received from the host system into command instructions to access the memory device 109 and/or the memory device 110 as well as convert responses associated with the memory device 109 and/or the memory device 110 into information for the host system 102.

The memory sub-system 103 can also include additional circuitry or components that are not illustrated. In some embodiments, the memory sub-system 103 can include a cache or buffer (e.g., DRAM) and address circuitry (e.g., a row decoder and a column decoder) that can receive an address from the memory sub-system controller 105 and decode the address to access the memory device 109 and/or the memory device 110.

In some embodiments, the memory device 109 includes local media controllers 111 that operate in conjunction with memory sub-system controller 105 to execute operations on one or more memory cells of the memory devices 109. An external controller (e.g., memory sub- system controller 105) can externally manage the memory device 109 (e.g., perform media management operations on the memory device 109). In some embodiments, a memory device 109 is a managed memory device, which is a raw memory device combined with a local controller (e.g., local controller 111) for media management within the same memory device package. An example of a managed memory device is a managed NAND (MNAND) device.

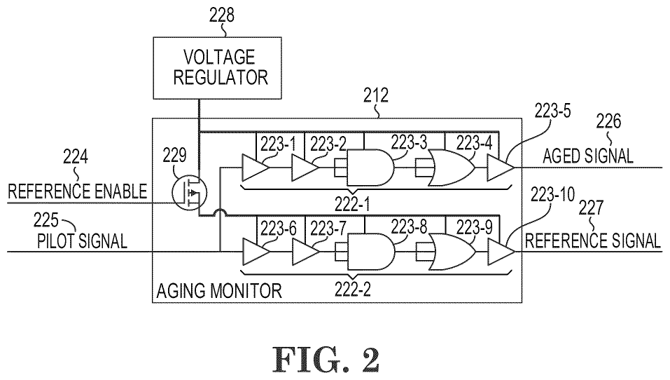

The memory sub-system 103 can include aging control circuitry 108. Although not shown in FIG. 1 so as to not obfuscate the drawings, the aging control circuitry 108 can include various circuitry to facilitate aspects of the disclosure described herein in FIG. 2. In some embodiments, the aging control circuitry 108 can include special purpose circuitry in the form of an ASIC, FPGA, state machine, hardware processing device, and/or other logic circuitry that can allow the aging control circuitry 108 to access memory such as the local memory 107, in accordance with the disclosure. In various instances, the aging control circuitry 108 can be external to the memory sub-system controller 105.

In some embodiments, the memory sub-system controller 105 includes at least a portion of the aging control circuitry 108. For example, the memory sub-system controller 105 can include a processor 106 (processing device) configured to execute instructions stored in local memory 107 for performing the operations described herein. In some embodiments, the aging control circuitry 108 is part of the host system 103, an application, or an operating system. The aging control circuitry 108 can be resident on the memory sub-system 103 and/or the memory sub-system controller 105. As used herein, the term “resident on” refers to something that is physically located on a particular component. For example, the aging control circuitry 108 being “resident on” the memory sub-system 103 refers to a condition in which the hardware circuitry that comprises the aging control circuitry 108 is physically located on the memory sub-system 103. The term “resident on” may be used interchangeably with other terms such as “deployed on” or “located on,” herein.

The memory sub-system 103 can also include an aging monitor 112 and measurement circuitry 136. The aging control circuitry 108 can control the aging monitor 112 and the measurement circuitry 136. The aging control circuitry 108 can control the aging monitor 112 to cause the aging monitor 112 to generate two or more signals. The measurement circuitry 136 can compare the two or more signals against each other to measure a deterioration of the memory sub-system 103.

The aging control circuitry 108 can utilize a first circuitry and a second circuitry to generate a first signal and a second signal, respectively. The first circuitry can be aged to simulate the aging of the memory sub-system 103. The second circuitry can be a reference circuitry. The first signal and the second signal can reflect the deterioration of the first circuitry and the second circuitry, respectively. The measurement circuitry 136 can measure the deterioration of the first circuitry using the second circuitry as a reference. The measurement circuitry 136 can provide the measured deterioration to the aging control circuitry 108. The aging control circuitry 108 can utilize the measured deterioration of the first circuitry to determine a deterioration of the memory sub-system 103. The aging control circuitry 108 can utilize the deterioration of the memory sub-system 103 to determine whether to take corrective actions to minimize the effects of the deterioration of the memory sub-system 103 and/or to determine what corrective action to take to minimize the effects of the deterioration of the memory sub-system 103. Although the examples provided herein are given in the context of the memory sub-system 103, the examples are also applicable to other systems such as system 100 and/or the host 102.

FIG. 2 illustrates a block diagram of an aging monitor 212 in accordance with some embodiments of the present disclosure. The aging monitor 212 includes chaining circuitry 222-1, 222-2, and power circuitry 229. The chaining circuitry 222-1 includes gates 223-1, 223-2, 223-3, 223-4, 223-5. The chaining circuitry 222-2 includes gates 223-6, 223-7, 223-8, 223-9, 223-10. The gates 223-1, 223-2, 223-3, 223-4, 223-5, 223-6, 223-7, 223-8, 223-9, 223-10 can be referred to as gates 223.

The voltage regulator 228 can provide power to the aging monitor 212. For example, the voltage regulator 228 can provide power to the chaining circuitry 222-1 continuously. The voltage regulator 228 can provide power to the chaining circuitry 222-2 periodically. For instance, the power circuitry 229 can gate power to the chaining circuitry 222-2 based on the reference enable signal 224. The power circuitry 229 can be a power switch among other types of circuitries that can be implemented to gate power to the chaining circuitry 222-2. The reference enable signal 224 can be provided from a controller such as the aging control circuitry 108 and/or the processing unit 104 of FIG. 1. The controller can provide the reference enable signal 224 to cause power to be provided from the voltage regulator 228 to the chaining circuitry 222-2.

The pilot signal 225 can be provided to the chaining circuitry 222-1 and the chaining circuitry 222-2 continuously. When powered, the chaining circuitry 222-1 can generate an aged signal 226 and the chaining circuitry 222-2 can generate a reference signal 227. The pilot signal 225 can switch between high and low values. The pilot signal 225 can also be used to obtain a particular aging profile for the chaining circuitry 222-1 and/or the chaining circuitry 222-2 due to switching related degradation. For example, an aging profile of the chaining circuitry 222-1 and/or the chaining circuitry 222-2 generated using a pilot signal 225 with a high duty cycle can be different than an aging profile of the chaining circuitry 222-1 and/or the chaining circuitry 222-2 generated using a pilot signal 225 with a low duty cycle. The pilot signal 225 that switches between high and low values can be provided continuously to the chaining circuitry 222-1, 222-2. Providing a switching pilot signal 225 to the chaining circuitry 222-1, 222-2 can allow for degradation to be measured. The pilot signal 225 can be referred to as a switching pilot signal 225 if the pilot signal 225 switches between a high and low value or a static pilot signal 225 if the pilot signal 225 maintains a constant value (e.g., does not switch between a high and low value).

The chaining circuitry 222-1 can be identical to the chaining circuitry 222-2. The chaining circuitry 222-1 and the chaining circuitry 222-2 can be different instances of a same chaining circuitry. The chaining circuitry 222-1, 222-2 includes logical cells. The logical cells can include flip-flops, latches, level shifters, and/or logic gates (e.g., gates 223), among other possible logical cells. The chaining circuitry 222-1, 222-2 can include NOT gates, AND gates, OR gates, and/or buffer gates, among other types of logic gates. However, the chaining circuitry 222-1, 222-2 can include other logical gates such as flip-flops and latches etc.

The gates 223 can be chained. For example, the output of the gate 223-1 is provided as an input to the gate 223-2, the output of the gate 223-2 is provided as an input to the gate 223-3, the output of the gate 223-3 is provided as an input to the gate 223-4, and the output of the gate 223-4 is provided as an input to the gate 223-5. The output of the gate 223-5 can be the aged signal 226. The output of the gate 223-6 is provided as an input to the gate 223-7, the output of the gate 223-7 is provided as an input to the gate 223-8, the output of the gate 223-8 is provided as an input to the gate 223-9, and the output of the gate 223-9 is provided as an input to the gate 223-10. The output of the gate 223-10 can be the reference signal 227.

Providing power continuously to the chaining circuitry 222-1, providing power periodically to the chaining circuitry 222-2, and providing a switching pilot signal, if necessary, to the chaining circuitry 222-1 and/or the chaining circuitry 222-2 can cause the chaining circuitry 222-1 to age differently than the chaining circuitry 222-2. For example, the chaining circuitry 222-1 can receive power continuously to follow the power scheme of the system (e.g., the memory sub-system). The chaining circuitry 222-1 can receive power when the system receives power and may not receive power when the system does not receive power. Providing power to the chaining circuitry 222-1 in line with the power scheme of the system can cause the chaining circuitry 222-1 to age at a same rate or a similar rate as the system. In various instances, the chaining circuitry 222-1 can receive power in line with a power scheme of a portion of the system. The portion of the system can include devices of the system and/or circuitry of the system. For instance, the chaining circuitry 222-1 can receive power if the decoding circuitry of the system receives power or if a memory device of the system receives power.

The chaining circuitry 222-2 can age differently than the chaining circuitry 222-1 because the chaining circuitry 222-2 does not follow the power scheme of the system and/or because the switching pilot signal 225 is provided to the chaining circuitry 222-1 and/or the chaining circuitry 222-2. For instance, the chaining circuitry 222-2 may not receive power until a determination is made to measure the deterioration of the chaining circuitry 222-1 to determine the deterioration of the system. The chaining circuity 222-2 can receive power to generate the reference signal 227. The chaining circuitry 222-2 can be powered off once the reference signal 227 is generated and/or measured.

The aged signal 226 can be referred to as “aged” because the aged signal 226 is generated with the chaining circuitry 222-1 that reflects the aging of the system and/or portions of the system. The reference signal 2227 is referred to as a “reference” because the reference signal 227 is generated with the chaining circuitry 222-2 that reflects the original state of the system or a state of the system that is younger than the actual age of the system. As used herein, the age of the system can reference a length of time the system has been in use, an intensity of the usage, and/or a deterioration that the system has experienced due to use of the system and/or the conditions under which the system is used. The conditions under which the system is used can include a temperature and/or a voltage, among others, of the system when the system is utilized. The aging of the system can accelerate considerably if the system is utilized at a higher temperature or with a particular voltage. For example, a system that is utilized with a high temperature can experience greater deterioration than a system that is utilized with a lower temperature.

The rate or pace of deterioration that the system experiences can be greater for newly manufactured products as compared to systems that have been utilized for a considerable duration of time. For example, the rate or deterioration that the system experiences can slow down as the system is utilized. To address the faster aging of new products the aging monitor 212 can generate the reference signals 227 more often than an aging monitor of an aged system.

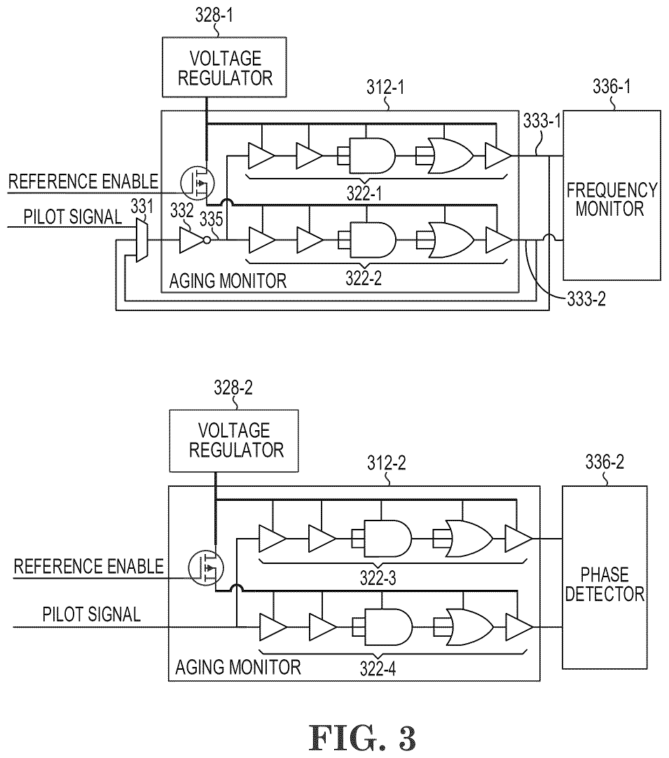

FIG. 3 illustrates a block diagram of various aging monitors 312-1, 312-2 coupled to multiple measurement circuitry 336-1, 336-2 in accordance with some embodiments of the present disclosure. The aging monitor 312-1 can include chaining circuitry 322-1, 322-2, a multiplexor (MUX) 331, and a NOT gate 332. Although the MUX 331 is shown as being outside the aging monitor 312-1, the MUX 331 can also be implemented inside the aging monitor 312-1. The aging monitor 312-2 includes chaining circuitry 322-3, 322-4. The aging monitor 312-1 can provide a reference signal and an aged signal to the measurement circuitry 336-1. The aging monitor 312-2 provides a reference signal and an aged signal to the measurement circuitry 336-2. In various instances, a single signal can be provided to the measurement circuitry 336-1. For example, an additional MUX (not shown) can receive the reference signal and the aged signal and can provide one of the reference signals and the aged signal to the measurement circuitry. The additional MUX can select the reference signal or the aged signal based on the signal that the MUX 331 selects.

The MUX 331 and the inverter 332 can be used to put the chaining circuitry 322-1 or the chaining circuitry 322-2 into oscillation mode. A frequency for the chaining circuitry 322-1 can be measured and a different frequency for the chaining circuitry 322-2 can be measured based on the MUX 331 and/or one or more additional MUXs (not shown). After measuring the frequencies of the chaining circuitries 322-1, 322-2, an age of the chaining circuitry 322-1 can be assessed using the frequencies of the chaining circuitry 322-1 and the chaining circuitry 322-2. For example, the ageing of the chaining circuitry 322-1 can be calculated by dividing the frequencies of the chaining circuitry 322-1, 322-2.

Although a single monitor 336-1 is shown to measure the frequencies of the chaining circuitry 322-1, 322-2, other examples can utilize two monitors (e.g., the monitor 336-1 and a different monitor not shown) to measure both frequencies (e.g., a frequency of the chaining circuitry 322-1 and a frequency of the chaining circuitry 322-2) simultaneously. For example, a first monitor can measure the frequency of the chaining circuitry 322-1 and a second monitor can measure the frequency of the chaining circuitry 322-2 at relatively the same time. In the example of FIG. 3, the frequencies of the chaining circuitry 322-1, 322-2 can be measured sequentially given that a single monitor 336-1 is used. An additional MUX (not shown_ can be used to measure the frequencies of the chaining circuitries 322-1, 322-2 sequentially.

The aging monitor 312-2 does not utilize a MUX because the phase detector 336-2 measures a phase shift (e.g., a difference in total chain delay) between the chaining circuitry 322-3 and the chaining circuitry 322-4. A pilot signal can enter the chaining circuitries 322-3, 322-4 synchronously and can exit the chaining circuitry 322-3, 322-4 with a phase shift that is the result of the aging of the chaining circuitry 322-3. The measurement of the phase shift can be used to determine the aging of the changing circuitry 322-3.

In various instances, the deterioration of the system can be measured and/or generated by measuring a deterioration of the chaining circuitry 322-1, 322-3. A timing deterioration can be measured by the measurement circuitry 336-1, 336-2. As used herein, a timing deterioration is a difference in the timing of a system as compared to the original system. A timing deterioration can be expressed as a slower propagation of a signal through multiple gates of the system as compared to the propagation of the signal through the multiple gates of the original system. The timing deterioration can be measured utilizing a frequency ratio measurement performed by the measurement circuitry 336-1 (e.g., frequency monitor). The timing deterioration can also be measured utilizing a phase measurement performed by the measurement circuitry 336-2 (e.g., phase detector).

To measure the frequency ratio utilizing the measurement circuitry 336-1, the chaining circuitry 322-1, 322-2 can be made self-oscillating by closing the loops of the chaining circuitry 322-1, 322-2. A loop of the chaining circuitry 322-1, 322-2 can include the output lines 333-1, 333-2, and the line 335. The loop can be closed utilizing the MUX 331. For example, the MUX 331 can couple the output lines 333-1, 333-2 to the line 335. The output of the MUX 331 can be inverted utilizing the NOT gate 332 prior to providing the signals, provided by the lines 333-1, 333-2, to the line 335. The NOT gate 332 can invert the output of the MUX 331 to put the chaining circuitry 332-1, 332-2 into self-oscillation. The NOT gate 332 may be omitted if the chain circuitry 332-1, 332-2 already invert the signal.

The MUX 331 can couple a line that provides the pilot signal, the line 333-1 that provides the aged signal of the chaining circuitry 322-1, and the line 333-2 that provides the reference signal of the chaining circuitry 322-2 to the line 335.

The frequency of the chaining circuitry 322-1, 322-2 can be measured by the measurement circuitry 336-1. The measurement circuitry 336-1 can calculate the deterioration based on the two frequency ratios generated from the frequencies of the chaining circuitry 322-1, 322-2. The measurement circuitry 336-1 can generate the first frequency ratio utilizing the chaining circuitry 322-1 and the second frequency ratio utilizing the chaining circuitry 322-2. In some examples, the measurement circuitry 336-1 can generate the frequencies and a different circuitry (e.g., aging control circuitry) can generate the frequency ratios and can generate the deterioration based on the ratios. The benefits of performing a frequency ratio measurement are that the frequency ratio measurement can be more accurate in measuring deterioration and can be more robust than performing a phase measurement.

However, performing a frequency ratio measurement can power the chaining circuitry 322-2 (e.g., reference circuitry) longer than performing the phase measurement powers the chaining circuitry 322-4 which can result in the chaining circuitry 322-2 aging faster than the chaining circuitry 322-4. Performing a frequency ratio measurement can also include subjecting the chaining circuitry 322-2 to higher oscillation frequencies than the chaining circuitry 322-4 which can also lead the chaining circuitry 322-2 to experience faster deterioration than the chaining circuitry 322-4. Further, performing the frequency ratio measurement can also include calculating the frequency ratios which can utilize circuitry in the measurement circuitry 336-1 not utilized by the measurement circuitry 336-2 causing the measurement circuitry 336-1 to be more expensive to manufacture and causing the measurement circuitry 336-1 to utilize more power than the measurement circuitry 336-2.

The phase of the chaining circuitry 322-3, 322-4 can be measured by the measurement circuitry 336-2. The measurement circuitry 336-2 can measure the timing difference between the chaining circuitry 322-3, 322-4 based on the phases of the chaining circuitry 322-3, 322-4. The pilot signal propagated through the chaining circuitry 322-3 (e.g., aged circuitry) and the chaining circuitry 322-4 (e.g., reference circuitry) can arrive at the measurement circuitry 336-2 with different phases. The measurement circuitry 336-2 measure the different phases and/or the difference between the phases.

The measurement circuitry 336-2 can measure the phases of the chaining circuitry 322-3, 322-4 directly via a high-speed clock or can apply circuitry similar to a delay-locked loop (DLL) that is self-adjusting circuitry and can count taps added to zero the phase. A DLL can align phases by adding some delays to the earlier line(s). These delays are buffers which can be referred to as taps. The buffers can be of a same type, called same weight, or of a different type. Utilizing buffers of different types (e.g., different weights) can indicate different delays. A DLL (e.g., DLL control) can MUX in and out as many such delays as needed to balance the two phases. Once the two phases are balanced, the DLL can determine the phase shift by the count of such delays (taps) and their type (weight).

Measuring the phase of the chaining circuitry 322-3, 322-4 can include powering the chaining circuitry 322-4 for less time than the chaining circuitry 322-2 which can cause the chaining circuitry 322-4 to age slower than the chaining circuitry 322-2. Measuring the phase of the chaining circuitry 322-3, 322-4 can include powering the chaining circuitry 322-4 for a lower duration as compared to the chaining circuitry 322-2 which can cause the chaining circuitry 322-4 to age slower than the chaining circuitry 322-2. Measuring the phases of the chaining circuitry 322-3, 322-4 to calculate the deterioration of the chaining circuitry 322-3 may not utilize firmware of math-capable circuitry which can make the measurement circuitry 336-2 less expensive and can make the measurement circuitry 336-2 utilize less power than the measurement circuitry 336-1. However, the measurement circuitry 336-2 can be less accurate than the measurement circuitry 336-1. Creating a high-resolution measurement circuitry 336-2 (e.g., high resolution phase detector) can be more complex than the measurement circuitry 336-1 (e.g., frequency monitor).

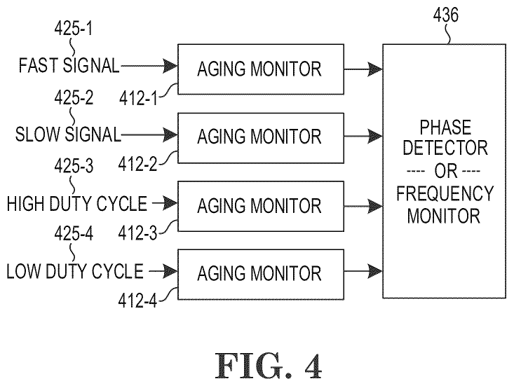

FIG. 4 illustrates a block diagram of multiple aging monitors 412-1, 412-2, 412-3, 412-4 coupled to measurement circuitry 436 in accordance with some embodiments of the present disclosure. The aging monitors 412-1, 412-2, 412-3, 412-4 can be referred to as aging monitors 412. Each of the aging monitors 412 can correspond to the aging monitor 212 of FIG. 2 or the aging monitors 312-1, 312-2 of FIG. 3.

The aging monitors 412 can receive a number of pilot signals 425-1, 425-2, 425-3, 425-4. For instance, the aging monitor 412-1 can receive the pilot signal 425-1, the aging monitor 412-2 can receive the pilot signal 425-2, the aging monitor 412-3 can receive the pilot signal 425-3, and the aging monitor 412-4 can receive the pilot signal 425-4. The pilot signals 425-1, 425-2, 425-3, 425-4 can be referred to as pilot signals 425.

Each of the pilot signals 425 can differ from the other pilot signals. For example, the pilot signal 425-1 can be a fast signal, the pilot signal 425-2 can be a slow signal, the pilot signal 425-3 can be a high duty cycle signal, and the pilot signal 425-4 can be a low duty cycle, among other possible differences between the pilot signals 425. The pilot signal 425-1 and the pilot signal 425-2 can be fast or slow, respectively, as compared to a threshold and/or as compared to each other. For instance, the pilot signal 425-1 can be fast as compared to the pilot signal 425-2. Fast signals and slow signals can reference a frequency of the signal as being fast or slow.

The frequency of the signal can be fast or slow relative to each other or a threshold, as previously stated. The duty cycle is a metric of asymmetricity. A symmetrical wave can have a 50% duty cycle (e.g., upper wave duration divided by the wave period). A high duty cycle can indicate that the upper wave (e.g., 1 in a digital world) is longer than 0. A low duty cycle can indicate that the upper wave is shorter than 0. A high duty cycle and a low duty cycle can activate a reference circuitry. For example, the upper wave can activate some transistors while the lower wave can activate other transistors. A 50% duty cycle can activate all the transistors in the same proportion. High duty cycles and low duty cycles can activate either one or another group of transistors for more time than others. Most systems do not switch symmetrically and are used non-stop. When some circuitry stops, it has some transistors open and other transistors closed. The duration of the transistor's work can be very different. A determination can be made as to what happens in circuitry that does not switch all the time and does not switch in a symmetrical manner based on having different duty cycle measurements.

The duty cycles can be high or low relative to each other or relative to a threshold. The differences shown between the pilot signals 425 (e.g., high signal vs. slow signal, high duty cycle vs. low duty cycle) are exemplary. Other differences can be applied to the pilot signals 425.

The aging mechanisms can include Channel Hot Carrier (CHC) (e.g., hot electrons) and Negative Bias Temperature Instability (NBTI), and/or Electromigration, among other examples of aging mechanisms. The examples of aging mechanisms are given as illustrative and not limiting. Other examples of aging mechanisms can be implemented in relation with the examples provided herein,

The pilot signals 425 can be selected based on an aging mechanism that is monitored. For example, a first aging monitor and a first pilot signal can be used to emulate the deterioration experienced by the hot electrons (CHC) of the system while a second aging monitor and a second pilot signal are used to emulate the deterioration experienced due to Negative Bias Temperature Instability (NBTI). The first pilot signal can be generated based on characteristics of the CHC and the second pilot signal can be generated to address characteristics of the NBTI. Although the examples provided herein are given in terms of the characteristics of the CHC and characteristics of the NBTI, other characteristics can be utilized.

The pilot signals 425, a monitor connection, and the cells used in the monitor can also be selected based on power domains (e.g., power scheme variance), clock domains (e.g., clock frequency and activity variance), dominating cell types (e.g., cell voltage thresholds or cell channel lengths), topology (e.g., place on the die), and/or temperature, among other characteristics utilized in the system. Clock domains can be addressed by different frequency pilot signals. To address power and voltage domains the monitors can be powered with the appropriate domains. To address different voltage thresholds and channel length cells a monitor can be created from the cells representing those thresholds and channel lengths. The pilot signals 425 can be selected based on different locations on a die (e.g., hot vs. cold areas) of the system. For example, a first location of a die of the system can experience temperatures above a threshold while a second location of the die experiences temperatures below the threshold. A first pilot signal can be selected to cause an aging monitor (e.g., an aging circuitry of the aging monitor) to deteriorate consistent with the deterioration experienced by circuitry in the first location.

Due to the infrequent measurements conducted by the measurement circuitry 436, a single measurement circuitry 436 can be utilized to serve the aging monitors 412. In various examples, each of the aging monitors 412 can provide output signals to different measurement circuitry 436 or any two or more aging monitors 412 can provide output signals to a measurement circuitry 436.

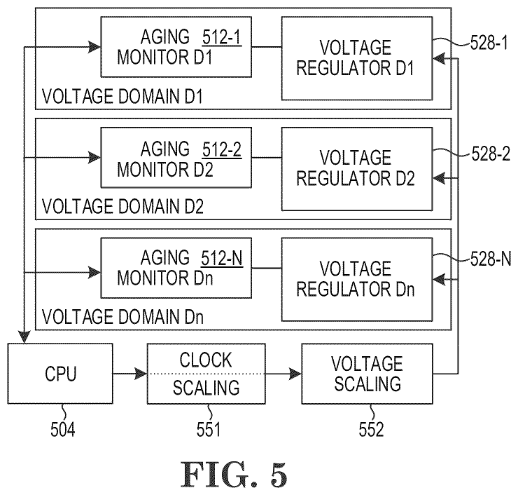

FIG. 5 illustrates a block diagram of multiple aging monitors 512-1, 512-2, . . . , 512-N that receive power from multiple voltage regulators 528-1, 528-2, . . . , 528-N in accordance with some embodiments of the present disclosure. The aging monitors 512-1, 512-2, . . . , 512-N can be referred to as aging monitors 512. The voltage regulators 528-1, 528-2, . . . , 528-N can be referred to as voltage regulators 528. The voltage regulators 528 can provide power to the aging monitors 512 and/or the device and/or system the monitor is dedicated for. For example, the voltage regulator 528-1 can provide power to the aging monitor 512-1, the voltage regulator 528-2 can provide power to the aging monitor 512-2, . . . , and the voltage regulator 528-N can provide power to the aging monitor 512-N. Although the example of FIG. 5 is provided in the context of voltage domains, the examples of FIG. 5 are equally applicable to clock domains, power domains, and area domains, among other domains.

Each of the voltage regulators 528 can provide power to the aging monitors 512 having a particular voltage. For example, the voltage regulator 528-1 can provide power having a first voltage to the aging monitor 512-1 while the voltage regulator 528-2 provides power having a second voltage to the aging monitor 512-2.

Each of the aging monitors 512 can generate an aged signal and a reference signal. The aged signals and the reference signals can be compared against each other to measure a deterioration of aged circuitry of the aging monitors 512. The measured deterioration can be provided to a controller of the system such as the CPU 504.

Upon determining some timing deterioration, the system (e.g., the CPU 504) can apply corrective actions to either extend the production lifetime of the system or restore a deteriorated performance of the system. For example, a clock of the system can be scaled down (e.g., clock scaling 551) to mimic the aged timing of the system. Scaling down the clock can extend error free operation of the system (e.g., circuitry of the system) for an additional duration of time.

An elevated voltage can be set to boost the deteriorated performance of the system. The voltage can be elevated utilizing voltage scaling 552. Elevating the voltage can also accelerate the aging of the system. Elevating the voltage can result in restoring performance for an additional duration of time.

In some examples, to offset the deterioration of the system, the system can be set to a lower voltage from the time the system is first utilized. Utilizing the system with a lower voltage can extend the life of the system. Both clock and voltage scaling can be used to achieve a desired performance of the system and/or extend the life of the system. The changes made to the clock (e.g., clock scaling 551) and/or the voltage (e.g., voltage scaling) can be reflected in the power provided from the voltage regulators 528 to the aging monitors 512 and/or the system.

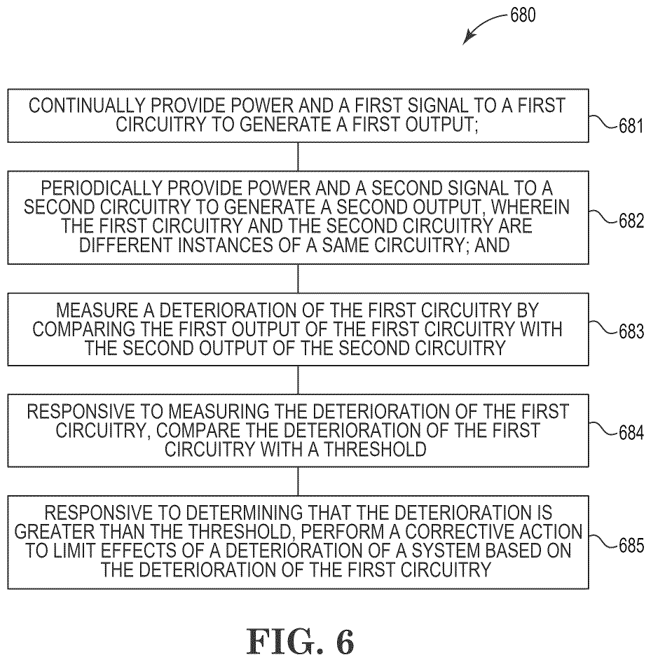

FIG. 6 is a flow diagram corresponding to a method 680 for implementing deterioration correction circuitry in accordance with some embodiments of the present disclosure. The method 680 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 680 is performed by the aging control circuitry 108 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

The method 680 includes controlling deterioration correction circuitry. At operation 681, power and a first signal can be provided continually to a first circuitry 222-1 of FIG. 2 to generate a first output. The first circuitry can reflect an age and/or a deterioration experienced by a system and/or a portion of the system. At operation 682, power and a second signal can be provided periodically to a second circuitry 222-2 of FIG. 2 to generate a second output. The first circuitry and the second circuitry are different instances of a same circuitry. The first circuitry and the second circuitry can be a same circuitry because both the first circuitry and the second circuitry include the same logical gates. For example, the first circuitry can include an AND gate and the second circuitry can also include an AND gate. The second circuitry can be a reference circuitry. The first circuitry and the second circuitry can be included in an aging monitor 212 of FIG. 2.

At operation 683, a deterioration of the first circuitry can be measured by comparing the first output of the first circuitry with the second output of the second circuitry. The first output can be a first signal and the second output can be a second signal. The first output can be an aged signal and the second output can be a reference signal. Measurement circuitry 136 of FIG. 1 can measure the first signal and the second signal and/or can compare the first signal and the second signal to measure a deterioration of the first circuitry. The deterioration of the first circuitry can reflect the deterioration of the system given that the power profile of the first circuitry can reflect the power profile of the system and/or a portion of the system.

At operation 684, responsive to measuring the deterioration of the first circuitry, the deterioration of the first circuitry can be compared with a threshold. The aging control circuitry 108 of FIG. 1 can compare the deterioration (e.g., measurement of the deterioration) to the threshold. The measurement circuitry can provide the deterioration measurement(s) to the aging control circuitry.

At operation 685, responsive to determining that the deterioration is greater than the threshold, a corrective action can be performed to limit effects of a deterioration of a system based on the deterioration of the first circuitry. The aging control circuitry can perform the corrective action(s).

In various instances, power can be provided to the second circuitry at a same time as power is provided to the first circuitry to generate the second output. A majority of the time power may be provided to the first circuitry and may not be provided to the second circuitry. Power may be provided to the second circuitry when deterioration measurements are requested. The first output can be generated continuously while the second output is generated when the second circuitry receives power. The deterioration measurements can be generated if the first circuitry and the second circuitry receive power at a same time to generate the first output and the second output at the same time.

The signals received by the first circuitry and the second circuitry can be a same signal. For instance, the first signal and the second signal can be same signal referred to as a pilot signal. In various examples, the second signal and the first signal can be an inverse signal of a signal provided to the first circuitry and the second circuitry by control circuitry. For instance, the control circuitry can provide a pilot signal. The pilot signal can be inverted utilizing a NOT gate to provide an inverted pilot signal to the first circuitry and the second circuitry.

Responsive to determining to measure a deterioration of the first circuitry, power can be provided to the second circuitry. The second circuitry can remain unpowered until a determination is made to measure the deterioration of the first circuitry. Responsive to generating the second output, the aging control circuitry can refrain from providing power to the second circuitry. Power can be withheld from the second circuitry after the second circuitry generates the second output. Withholding power from the second circuitry until the second output is requested and after the second output is generated can guarantee that the second circuitry remains unpowered a majority of the time which can limit the effects of aging as compared to the first circuitry which remains powered continuously.

In various instances, the first circuitry can include a first plurality of logic cells and the second circuitry include a second plurality of logic cells. The logic cells can be, for example, a logical gate, among other possible logic cells. The first plurality of logic cells and the second plurality of logic cells can be different instances of a same plurality of logic cells. For instance, the first plurality of logic cells can include a first AND gate and the second plurality of logic cells includes a second AND gate among other types of logic cells such as flip flops, latches, and registers etc. The logic cells can be chained such that the output of one of the logic cells is an input to a next logical cell. The logic cells can be chained to generate an output. For instance, the first plurality of logic cells is chained to generate the first output and the second plurality of logic cells are chained to generate a second output.

In various instances, an aging monitor can include a first circuitry comprising a first chain of logic cells and a second circuitry comprising a second chain of logic cells. The first chain of logic cells and the second chain of logic cells are a same chain of logic cells. The first circuitry and the second circuitry can be different instances of a same chain of logic cells. A control circuitry can be coupled to the first circuitry and the second circuitry. The control circuitry can provide power and a signal to the first circuitry to generate an aged signal. The power to the first circuitry can be provided continuously. Power and the signal can be provided discontinuously to the second circuitry to generate a reference signal. Power is provided to the second circuitry based on a determination to measure a deterioration of the first circuitry. The signal can be provided continuously to the first circuitry and the second circuitry.

Responsive to measuring the deterioration of the first circuitry, power can be withheld from the second circuitry. For example, a controller can refrain from providing power to the second circuitry responsive to measuring the deterioration of the first circuitry.

A system can also include measurement circuitry coupled to the first circuitry and the second circuitry. The measurement circuitry can compare the aged signal to the reference signal. The measurement circuitry can measure the deterioration of the first circuitry as compared to the second circuitry using a comparison of the aged signal to the reference signal.

In various instances, the first circuitry and the second circuitry can be made self-oscillating by closing a loop via a MUX, another gate, and/or by other means. The loop can include coupling a first output line of the first circuitry and a second output line of the second circuitry with an input line that provides the signal to the first circuitry and the second circuitry. For example, the aging monitor can include the MUX and a NOT gate. The MUX and the NOT gate can also be implemented outside the aging monitor. The MUX can be implemented outside the aging monitor while the NOT gate is implemented within the aging monitor. The NOT gate is further configured to receive an output of the MUX and invert the output of the MUX to generate the signal provided to the first circuitry and the second circuitry.

The measurement circuitry can compare the aged signal to the reference signal to generate a frequency ratio measurement. The measurement circuitry can compare the aged signal to the reference signal to measure a timing difference between the aged signal and the reference signal. The measurement circuitry can utilize the timing difference to generate the deterioration measurement. The system can also include one or more voltage regulators to provide power to the second circuitry based on receipt of a reference enable signal.

In various instances, a system can include an apparatus that includes a first aging monitor including a first reference circuitry and a first aging circuitry. The apparatus can also include a second aging monitor including a second reference circuitry and a second aging circuitry. Control circuitry can provide a first signal to the first aging monitor to generate a first output utilizing the first reference circuitry and a second output utilizing the first aging circuitry. The control circuitry can provide a second signal to the second aging monitor to generate a third output utilizing the second reference circuitry and a fourth output utilizing the second aging circuitry. Measurement circuitry can compare the first output to the second output of the first aging monitor to determine a first deterioration measurement of a first portion of the apparatus. The measurement circuitry can compare the third output to the fourth output of the second aging monito to determine a second deterioration measurement of a second portion of the apparatus.

The control circuitry can utilize the first deterioration measurement to take corrective actions to mitigate the effects of the deterioration of the first portion of the apparatus. The control circuitry can utilize the second deterioration measurement to take corrective actions to mitigate the effects of the deterioration of the second portion of the apparatus.

The first signal and the second signal can be different pilot signals. The first signal and the second signal can be selected to identify a deterioration of a particular aspect of the apparatus. For example, the first signal and the second signal can be selected based on a timing deterioration of the apparatus and voltage drift of the apparatus, respectively, for example. The different pilot signals can be provided to the first aging monitor and the second aging monitor to address different aging effects of the first portion of the apparatus and the second portion of the apparatus, respectively.

The apparatus can also include power circuitry configured to provide a first power to the first aging monitor and a second power to the second aging monitor, wherein the first power is provided to the first portion of the apparatus and the second portion is provided to the second portion of the apparatus to mimic a power provided to the first portion of the apparatus and the second portion of the apparatus.

The control circuitry can perform a first correction action responsive to the first deterioration measurement to extend a life of the first portion of the apparatus or to restore a deteriorated performance to the first portion of the apparatus. The control circuitry can perform a second correction action responsive to the second deterioration measurement to extend a life of the second portion of the apparatus or to restore a deteriorated performance to the second portion of the apparatus.

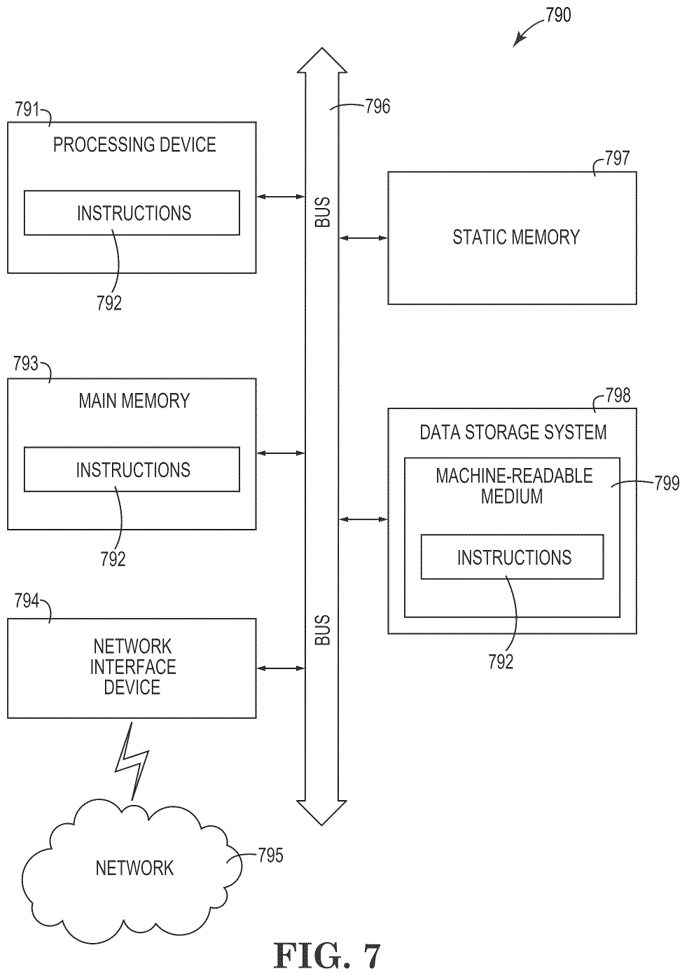

FIG. 7 is a block diagram of an example computer system in which embodiments of the present disclosure may operate. For example, FIG. 7 illustrates an example machine of a computer system 790 within which a set of instructions, for causing the machine to perform any one or more of the methodologies discussed herein, can be executed. In some embodiments, the computer system 790 can correspond to a host system (e.g., the host system 102 of FIG. 1) that includes, is coupled to, or utilizes a memory sub-system (e.g., the memory sub-system 103 of FIG. 1) or can be used to perform the operations of a controller (e.g., to execute an operating system to perform operations corresponding to the aging control circuitry 108 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 790 includes a processing device 791, a main memory 793 (e.g., read-only memory (ROM), flash memory, dynamic random access memory (DRAM) such as synchronous DRAM (SDRAM) or Rambus DRAM (RDRAM), etc.), a static memory 797 (e.g., flash memory, static random access memory (SRAM), etc.), and a data storage system 798, which communicate with each other via a bus 796.

The processing device 791 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. The processing device 791 can also be one or more special-purpose processing devices such as an application specific integrated circuit (ASIC), a field programmable gate array (FPGA), a digital signal processor (DSP), network processor, or the like. The processing device 791 is configured to execute instructions 792 for performing the operations and steps discussed herein. The computer system 790 can further include a network interface device 794 to communicate over the network 795.

The data storage system 798 can include a machine-readable storage medium 799 (also known as a computer-readable medium) on which is stored one or more sets of instructions 792 or software embodying any one or more of the methodologies or functions described herein. The instructions 792 can also reside, completely or at least partially, within the main memory 793 and/or within the processing device 791 during execution thereof by the computer system 790, the main memory 793 and the processing device 791 also constituting machine-readable storage media. The machine-readable storage medium 799, data storage system 798, and/or main memory 793 can correspond to the memory sub-system 103 of FIG. 1.

In one embodiment, the instructions 792 include instructions to implement functionality corresponding to search circuitry (e.g., the aging control circuitry 108 of FIG. 1). While the machine-readable storage medium 799 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, which manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general-purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMS, EEPROMs, magnetic or optical cards, or any type of media suitable for storing electronic instructions, each coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, which can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A method, comprising:
continually providing power and a first signal to a first circuitry to generate a first output;
periodically providing power and a second signal to a second circuitry to generate a second output, wherein the first circuitry and the second circuitry are different instances of a same circuitry;
measuring a deterioration of the first circuitry by comparing the first output of the first circuitry with the second output of the second circuitry;
responsive to measuring the deterioration of the first circuitry, comparing the deterioration of the first circuitry with a threshold; and
responsive to determining that the deterioration is greater than the threshold, performing a corrective action to limit effects of a deterioration of a system based on the deterioration of the first circuitry.

2. The method of claim 1, further comprising providing power to the second circuitry at a same time as power is provided to the first circuitry to generate the second output.

3. The method of claim 1, wherein the first signal and the second signal are a same signal.

4. The method of claim 1, wherein the second signal and the first signal are an inverse signal of a signal provided to the first circuitry and the second circuitry by control circuitry.

5. The method of claim 1, wherein further comprising, responsive to determining to measure a deterioration of the first circuitry, provide power to the second circuitry.

6. The method of claim 5, further comprising, responsive to generating the second output, refrain from providing power to the second circuitry.

7. The method of claim 1, wherein the first circuitry includes a first plurality of logical cells and the second circuitry include a second plurality of logical cells, and wherein the first plurality of logical cells and the second plurality of logical cells are different instances of a same plurality of logical cells.

8. The method of claim 7, wherein the first plurality of logical cells is chained to generate the first output and the second plurality of logical cells are chained to generate a second output.

9. An apparatus, comprising:
a first circuitry comprising a first chain of logical cells;
a second circuitry comprising a second chain of logical cells, wherein the first chain of logical cells and the second chain of logical cells are a same chain of logical cells;
control circuitry coupled to the first circuitry and the second circuitry; and configured to:
provide power and a signal to the first circuitry to generate an aged signal;
provide power and the signal to the second circuitry to generate a reference signal, wherein power is provided to the second circuitry based on a determination to measure a deterioration of the first circuitry and wherein the signal is continuously provided to the first circuitry and the second circuitry; and
refrain from providing power to the second circuitry responsive to measuring the deterioration of the first circuitry; and
measurement circuitry coupled to the first circuitry and the second circuitry, and configured to:
compare the aged signal to the reference signal; and
measure the deterioration of the first circuitry as compared to the second circuitry using a comparison of the aged signal to the reference signal.

10. The apparatus of claim 9, wherein the first circuitry and the second circuitry are made self-oscillating by closing a loop via a gate.

11. The apparatus of claim 9, wherein the first circuitry and the second circuitry are made self-oscillating by closing the loop via a gate, wherein the loop includes coupling a first output line of the first circuitry and a second output line of the second circuitry with an input line that provides the signal to the first circuitry and the second circuitry.

12. The apparatus of claim 9, wherein the measurement circuitry is further configured to compare the aged signal to the reference signal to generate a frequency ratio measurement.

13. The apparatus of claim 9, wherein the measurement circuitry is further configured to compare the aged signal to the reference signal to measure a timing difference between the aged signal and the reference signal.

14. The apparatus of claim 13, wherein the measurement circuitry is further configured to utilize the timing different to generate a deterioration measurement.

15. The apparatus of claim 9, further comprising a voltage regulator configured to provide power to the second circuitry based on receipt of a reference enable signal.

16. An apparatus, comprising:
a first aging monitor comprising a first reference circuitry and a first aging circuitry;
a second aging monitor comprising a second reference circuitry and a second aging circuitry;
control circuitry coupled to the first aging monitor and the second aging circuitry and configured monitor to:
provide a first signal to the first aging monitor to generate a first output utilizing the first reference circuitry and a second output utilizing the first aging circuitry;
provide a second signal to the second aging monitor to generate a third output utilizing the second reference circuitry and a fourth output utilizing the second aging circuitry;
measurement circuitry coupled to the first aging monitor and the second aging monitor and configured to:
compare the first output to the second output of the first aging monitor to determine a first deterioration measurement of a first portion of the apparatus; and
compare the third output to the fourth output of the second aging monitor to determine a second deterioration measurement of a second portion of the apparatus.

17. The apparatus of claim 16, wherein the first signal and the second signal are different pilot signals.

18. The apparatus of claim 17, wherein the different pilot signals are provided to the first aging monitor and the second aging monitor to address different aging effects.

19. The apparatus of claim 16, further comprising power circuitry configured to provide a first power to the first aging monitor and a second power to the second aging monitor, wherein the first power is provided to the first portion of the apparatus and the second power is provided to the second portion of the apparatus to mimic a power provided to the first portion of the apparatus and the second portion of the apparatus.

20. The apparatus of claim 16, wherein the control circuitry is further configured to:
perform a first correction action responsive to the first deterioration measurement to extend a life of the first portion of the apparatus or to restore a deteriorated performance to the first portion of the apparatus; and
perform a second correction action responsive to the second deterioration measurement to extend a life of the second portion of the apparatus or to restore a deteriorated performance to the second portion of the apparatus.
